(19) United States
(12) Patent Application Publication
(10) Pub. No.: US 2009/0001583 A1
(43) Pub. Date: Jan. 1, 2009

(54) METHOD OF MANUFACTURING SEMICONDUCTOR DEVICE

(75) Inventors: Cheol Mo Jeong, Icheon-si (KR); Whee Won Cho, Cheongju-si (KR); Seung Hee Hong, Seoul (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 12/019,945

(22) Filed: Jan. 25, 2008

(30) Foreign Application Priority Data
Jun. 29, 2007 (KR) 10-2007-0065015

(51) Int. Cl. H01L 21/768; H01L 23/52

(52) U.S. Cl. 257/751; 438/620; 257/E21.585; 257/E23.141

(57) ABSTRACT

The present invention relates to a semiconductor device and a method of fabricating the same. In an embodiment of the present invention, an insulating layer in which contact holes are formed is formed over a semiconductor substrate in which lower metal lines are formed. A barrier metal layer, having a stack structure of a first tungsten (W) layer and a tungsten nitride (WN) layer, is formed within the contact holes. Contact plugs are formed within the contact holes.

### CROSS-REFERENCES TO RELATED APPLICATIONS

The present application claims priority to Korean patent application number 10-2007-065015, filed on Jun. 29, 2007, which is incorporated by reference in its entirety.

### BACKGROUND OF THE INVENTION

The present invention relates to a semiconductor device and, more particularly, to a method of forming a contact plug with improved contact resistance and process steps.

In a process of forming contact plugs connecting lower metal lines made of a metal layer (in particular, a copper (Cu) layer) and an upper metal line made of a metal layer (in particular, an aluminum (Al) layer), if a barrier metal layer having a stack structure of a tantalum (Ta) layer and a tantalum nitride (TaN) layer is formed within the contact plugs, there is a high probability that cracks can occur in the barrier metal layer due to high stress.

Further, in the case where nitrogen (N₂) is flown in order to form a barrier metal layer on a surface of a contact hole when lower metal lines is opened using an etch process for forming the contact hole, a copper (Cu) layer (that is, the material of the lower metal lines) is combined with nitrogen (N₂), resulting in the formation of a Cu—N material having an insulating characteristic at the bottom of the contact hole. Accordingly, resistance fail occurs.

### BRIEF SUMMARY OF THE INVENTION

The present invention is directed towards the improved characteristic of a barrier metal layer with respect to lower metal lines made of a copper (Cu) layer by forming the barrier metal layer using a hybrid scheme, including a process of stuffing oxygen (O₂) atoms, after a stack structure of a tungsten (W) layer and a tungsten nitride (WN) layer is formed within a contact hole.

According to a method of fabricating a semiconductor device in accordance with an embodiment the present invention, an insulating layer in which contact holes are formed is formed over a semiconductor substrate in which lower metal lines are formed. A barrier metal layer, having a stack structure of a first tungsten (W) layer and a tungsten nitride (WN) layer, is formed within the contact holes. Contact plugs are formed within the contact holes.

The lower metal lines may be made of a copper (Cu) layer. A pre-cleaning process may be further performed after the contact holes are formed. The pre-cleaning process may be performed using a mixed gas of SiH₄ and H₂ gases and a plasma.

At the time of the formation process of the barrier metal layer, a second tungsten (W) layer may be further formed on the tungsten nitride (WN) layer. Each of the first tungsten (W) layer and the second tungsten (W) layer may be formed to a thickness of 20 to 200 angstrom. The tungsten nitride (WN) layer may be formed to a thickness of 100 to 1000 angstrom. The tungsten nitride (WN) layer may be formed in the same chamber as that in which the first tungsten (W) layer or the tungsten (W) layer is formed. The tungsten nitride (WN) layer may be formed on the first tungsten (W) by flowing an N₂ or NH₃ gas.

A process of stuffing the barrier metal layer with oxygen (O₂) atoms may be further performed after the barrier metal layer is formed. The stuffing process may be performed using an anneal or plasma process. The pre-cleaning process and the process of forming the barrier metal layer may be performed in-situ within one chamber. The contact plugs may be made of a tungsten (W) layer.

According to a method of fabricating a semiconductor device in accordance with another embodiment the present invention, a first insulating layer in which lower metal lines are formed is formed over a semiconductor substrate. A second insulating layer in which contact holes are formed is formed over the first insulating layer and lower metal lines. A barrier metal layer is formed within the contact holes. A process of stuffing the barrier metal layer with oxygen (O₂) atoms is performed. Contact plugs are formed by gap filling the contact holes with a conductive layer. Upper metal lines are formed on the contact plugs.

The lower metal lines may be made of a copper (Cu) layer. A pre-cleaning process may be further performed after the contact holes are formed. The pre-cleaning process may be performed using a mixed gas of SiH₄ and H₂ gases and a plasma.

The barrier metal layer may have a stack structure of a tungsten (W) layer and a tungsten nitride (WN) layer. The barrier metal layer may have a stack structure of a first tungsten (W) layer, a tungsten nitride (WN) layer and a second tungsten (W) layer. The tungsten (W) layer may be formed to a thickness of 20 to 200 angstrom. Each of the first tungsten (W) layer and the second tungsten (W) layer may be formed to a thickness of 20 to 200 angstrom. The tungsten nitride (WN) layer may be formed to a thickness of 100 to 1000 angstrom. The tungsten nitride (WN) layer may be formed in the same chamber as that in which the first tungsten (W) layer or the tungsten (W) layer is formed. The tungsten nitride (WN) layer may be formed on the first tungsten (W) by flowing an N₂ or NH₃ gas.

After the barrier metal layer is formed, a process of stuffing the barrier metal layer with oxygen (O₂) atoms may be further performed. The stuffing process may be performed using an anneal or plasma process. The pre-cleaning process and the process of forming the barrier metal layer may be performed in-situ within one chamber. The contact plugs may be made of a tungsten (W) layer. The upper metal lines may be made of an aluminum (Al) layer.

A semiconductor device according to still another embodiment the present invention includes lower metal lines formed over a semiconductor substrate, an insulating layer including contact holes through which the lower metal lines are exposed over the semiconductor substrate including the lower metal lines, a barrier metal layer formed on sidewalls of the contact holes and the lower metal lines and including a first tungsten (W) layer and a tungsten nitride (WN) layer, and contact plugs formed on the barrier metal layer within the contact holes.

The lower metal lines may be made of a copper (Cu) layer. The insulating layer may be made of oxide. The barrier metal layer may further include a second tungsten (W) layer on the tungsten nitride (WN) layer. The first tungsten (W) layer may be formed to a thickness of 20 to 200 angstrom. The tungsten nitride (WN) layer may be formed to a thickness of 100 to 1000 angstrom. The second tungsten (W) layer may be formed to a thickness of 20 to 200 angstrom. The contact plugs may be made of a tungsten (W) layer.

### BRIEF DESCRIPTION OF THE DRAWINGS

FIGS. 1A to 1D are sectional views illustrating a semiconductor device and a method of fabricating the same according to embodiments of the present invention.

### DESCRIPTION OF SPECIFIC EMBODIMENTS

Specific embodiments according to the present invention will be described with reference to the accompanying drawings.

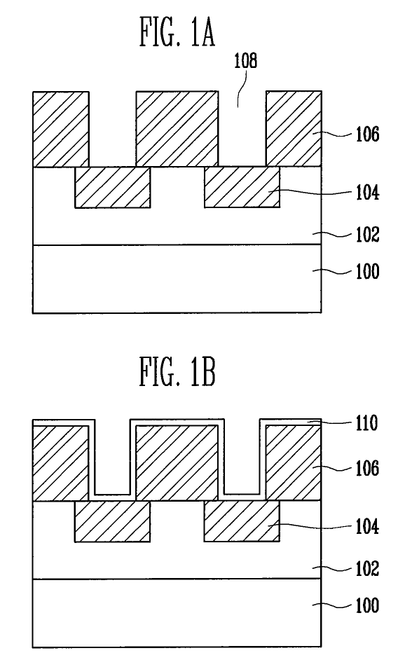

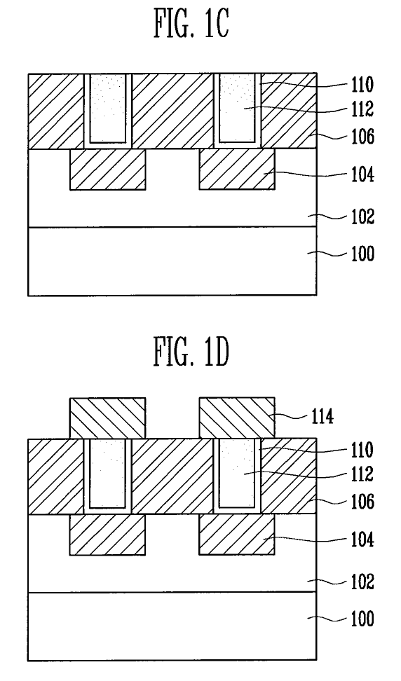

Referring to FIG. 1A, a first insulating layer 102 is formed over a semiconductor substrate 100 in which a number of elements for forming a semiconductor device are formed. The first insulating layer 102 may be made of oxide.

A damsacene pattern is formed within the first insulating layer 102 using a damascene process. The damsacene pattern is gap filled with a first conductive layer, thus forming lower metal lines 104. The first conductive layer may be made of a copper (Cu) layer.

A second insulating layer 106 is formed over the first insulating layer 102 and the lower metal lines 104. Contact holes 108 are formed by etching the second insulating layer 106 until the lower metal lines 104 are exposed using an etch process. The second insulating layer 106 may be made of oxide.

A pre-cleaning process is performed in order to minimize the loss of the lower metal lines 104. The pre-cleaning process may be performed using a mixed gas of SiH₄ and H₂ and a plasma in order to remove native oxide and polymer generated at the time of an etch process.

Referring to FIG. 1B, a stack structure of a tungsten (W) layer and a tungsten nitride (WN) layer is formed on the second insulating layer 106, including the inner walls of the contact holes 108. A barrier metal layer 110 is formed using a hybrid scheme involving a process of oxygen (O₂) stuffing. That is, oxygen atoms are provided between empty spaces between grain boundaries by allowing the oxygen atoms to travel through the paths defined by the grain boundaries. The barrier metal layer 110 may be formed to have a stack structure including a tungsten (W) layer and a tungsten nitride (WN) layer or a stack structure including a tungsten (W) layer, a tungsten nitride (WN) layer and a tungsten (W) layer. The barrier metal layer 110 may be formed using a Chemical Vapor Deposition (CVD) or Physical Vapor Deposition (PVD) method.

The method of forming the barrier metal layer 110 using the hybrid scheme including the process of oxygen (O₂) stuffing, after the stack structure of the tungsten (W) layer and the tungsten nitride (WN) layer is formed, is described in more detail below.

The tungsten (W) layer (as the barrier metal layer 110) is formed on a surface of the second insulating layer 106 and the contact holes 108. The tungsten (W) layer may be formed to a thickness of 20 to 200 angstrom. If the tungsten (W) layer is formed on the surface of the second insulating layer 106 and the contact holes 108 as described above, an adhesive characteristic with the contact resistance Rc can be improved.

The tungsten nitride (WN) layer is formed on the tungsten (W) layer by flowing N₂ or NH₃ gases into the same chamber as that in which the tungsten (W) layer has been formed. The tungsten nitride (WN) layer may be formed to a thickness of 100 to 1000 angstrom.

In order to fill the grain boundary portion of the barrier metal layer 110 (that is, the tungsten nitride (WN) layer) with oxygen (O₂) atoms, an anneal or plasma process is performed on the result in which the barrier metal layer 110 is formed. The anneal process is carried out within a furnace. The purpose of stuffing the grain boundary portion of the tungsten nitride (WN) layer with oxygen (O₂) atoms is to prohibit aluminum atoms of an aluminum (Al) layer, formed in a subsequent process, from being infiltrated into an active region through the tungsten nitride (WN) layer by enhancing the characteristic of the barrier metal layer 110 (that is, the tungsten nitride (WN) layer).

The pre-cleaning process and the formation process of the barrier metal layer 110 are formed in-situ within one chamber. If the barrier metal layer 110 has a stack structure including the tungsten (W) layer and the tungsten nitride (WN) layer as described above, a resistivity characteristic of about 4.4 μΩ×cm can be obtained.

Referring to FIG. 1C, a second conductive layer is formed on the contact holes 108 in such a way to gap fill the contact holes 108. Contact plugs 112 are formed by performing a CMP process or an etchback process until the second insulating layer 106 is exposed. The second conductive layer may be formed from a tungsten (W) layer. If the barrier metal layer 110 has the stack structure including the tungsten (W) layer and the tungsten nitride (WN) layer or the stack structure including the tungsten (W) layer, the tungsten nitride (WN) layer and the tungsten (W) layer as described above, a nucleation process can be omitted at the time of the second conductive layer formation process. If the nucleation process is omitted, the contact resistance Rc can be improved. The contact plugs 112 function to connect the lower metal lines 104 and upper metal lines to be formed in a subsequent process.

Referring to FIG. 1D, a third conductive layer is formed over the second insulating layer 106 and the contact plugs 112. Upper metal lines 114 are formed by performing an etch process such that the third conductive layer remains on the contact plugs 112. The third conductive layer may be made of an aluminum (Al) layer.

As described above, after the stack structure including the tungsten (W) layer and the tungsten nitride (WN) layer is formed within the contact holes, the barrier metal layer is formed using a hybrid scheme including the process of oxygen (O₂) stuffing. Accordingly, the characteristic of the barrier metal layer with respect to the lower metal lines made of the copper (Cu) layer can be improved.

Further, since the barrier metal layer is made of the tungsten (W) layer, a nucleation process can be omitted at the time of the tungsten (W) layer formation process for forming the contact plugs. Accordingly, the process can be simplified and therefore the contact resistance Rc can be improved.

Moreover, since a nucleation process is omitted, the contact resistance Rc can be improved.

In addition, since the tungsten (W) layer is formed on a surface of the contact holes, the contact resistance Rc and adhesive characteristic can be improved.

Incidentally, since the pre-cleaning process and the barrier metal layer (110) formation process are performed in-situ within one chamber, the process steps can be simplified.

The present invention is not limited to the disclosed embodiments, but may be implemented in various manners. The embodiments are provided to complete the disclosure of the present invention and to allow those having ordinary skill in the art to understand the scope of the present invention. The present invention is defined by the category of the claims.

What is claimed is:

1. A method of fabricating a semiconductor device, the method comprising:
forming a first insulating layer over a substrate, the first insulating layer having lower metal lines defined therein;
forming a second insulating layer over the first insulating layer;
forming through holes in the second insulating layer exposing the lower metal lines;
forming a barrier metal layer within the contact holes, the barrier metal layer having a stack structure including a first tungsten (W) layer and a tungsten nitride (WN) layer; and
forming plugs within the holes.

2. The method of claim 1, wherein the lower metal lines are made of a copper (Cu) layer.

3. The method of claim 1, further performing a pre-cleaning process after the holes are formed.

4. The method of claim 3, wherein the pre-cleaning process is performed using a mixed gas of SiH₄ and H₂ gases and a plasma.

5. The method of claim 1, wherein at the time of the formation process of the barrier metal layer, a second tungsten (W) layer is further formed on the tungsten nitride (WN) layer.

6. The method of claim 5, wherein each of the first tungsten (W) layer and the second tungsten (W) layer is formed to a thickness of 20 to 200 angstrom.

7. The method of claim 1, wherein the tungsten nitride (WN) layer is formed to a thickness of 100 to 1000 angstrom.

8. The method of claim 1, wherein the tungsten nitride (WN) layer is formed in the same chamber as that in which the first tungsten (W) layer or the tungsten (W) layer is formed.

9. The method of claim 1, wherein the tungsten nitride (WN) layer is formed on the first tungsten (W) by flowing an N₂ or NH₃ gas.

10. The method of claim 1, further comprising performing stuffing the barrier metal layer with oxygen (O₂) atoms after the barrier metal layer is formed.

11. The method of claim 10, wherein the oxygen is provided into the barrier metal layer by using an anneal or plasma process.

12. The method of claim 3, wherein the pre-cleaning process and the process of forming the barrier metal layer are performed in-situ within one chamber.

13. The method of claim 1, wherein the plugs are made of a tungsten (W) layer.

14. A method of fabricating a semiconductor device, the method comprising:
forming a first insulating layer in which lower metal lines are formed over a semiconductor substrate;
forming a second insulating layer in which holes are formed, the holes exposing the lower metal lines;
forming a barrier metal layer within the holes;
stuffing oxygen atoms into the barrier metal layer;
forming plugs by gap filling the holes with a conductive layer; and
forming upper metal lines on the plugs.

15. The method of claim 14, wherein the lower metal lines are made of a copper (Cu) layer.

16. The method of claim 14, further performing a pre-cleaning process after the holes are formed.

17. The method of claim 16, wherein the pre-cleaning process is performed using a mixed gas of SiH₄ and H₂ gases and a plasma.

18. The method of claim 14, wherein the barrier metal layer has a stack structure including a tungsten (W) layer and a tungsten nitride (WN) layer.

19. The method of claim 14, wherein the barrier metal layer has a stack structure includes a first tungsten (W) layer, a tungsten nitride (WN) layer and a second tungsten (W) layer.

20. The method of claim 18, wherein the tungsten (W) layer is formed to a thickness of 20 to 200 angstrom.

21. The method of claim 19, wherein each of the first tungsten (W) layer and the second tungsten (W) layer is formed to a thickness of 20 to 200 angstrom.

22. The method of any one of claims 19, wherein the tungsten nitride (WN) layer is formed to a thickness of 100 to 1000 angstrom.

23. The method of any one of claims 19, wherein the tungsten nitride (WN) layer is formed in the same chamber as that in which the first tungsten (W) layer or the tungsten (W) layer is formed.

24. The method of any one of claims 19, wherein the tungsten nitride (WN) layer is formed on the first tungsten (W) by flowing an N₂ or NH₃ gas.

25. The method of claim 14, wherein the stuffing process is performed using an anneal or plasma process.

26. The method of claim 16, wherein the pre-cleaning process and the process of forming the barrier metal layer are performed in-situ within one chamber.

27. The method of claim 14, wherein the plugs are made of a tungsten (W) layer.

28. The method of claim 14, wherein the upper metal lines are made of an aluminum (Al) layer.

29. A semiconductor device comprising:
lower metal lines formed over a semiconductor substrate;
an insulating layer including holes through which the lower metal lines are exposed, the insulating layer being provided over the semiconductor substrate and the lower metal lines;
a barrier metal layer formed on sidewalls of the holes and the lower metal lines and including a first tungsten (W) layer and a tungsten nitride (WN) layer; and
plugs formed on the barrier metal layer within the contact holes.

30. The semiconductor device of claim 29, wherein the lower metal lines are made of a copper (Cu) layer.

31. The semiconductor device of claim 29, wherein the insulating layer is made of oxide.

32. The semiconductor device of claim 29, wherein the barrier metal layer further includes a second tungsten (W) layer on the tungsten nitride (WN) layer.

33. The semiconductor device of claim 29, wherein the first tungsten (W) layer is formed to a thickness of 20 to 200 angstrom.

34. The semiconductor device of claim 29, wherein the tungsten nitride (WN) layer is formed to a thickness of 100 to 1000 angstrom.

35. The semiconductor device of claim 32, wherein the second tungsten (W) layer is formed to a thickness of 20 to 200 angstrom.

36. The semiconductor device of claim 29, wherein the contact plugs are made of a tungsten (W) layer.
